(19) United States
(12) Patent Application Publication
(10) Pub. No.: US 2010/0252921 A1
(43) Pub. Date: Oct. 7, 2010

(54) SEMICONDUCTOR DEVICE AND MANUFACTURING METHOD OF THE SAME

(75) Inventor: Fumimasa KATAGIRI, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/750,854

(22) Filed: Mar. 31, 2010

(30) Foreign Application Priority Data
Apr. 1, 2009 (JP) 2009-089223

(51) Int. Cl. H01L 23/52; H01L 21/60; H01L 23/522

(52) U.S. Cl. 257/692; 438/124; 257/774; 257/E21.506; 257/723; 257/E23.145; 257/E23.141

(57) ABSTRACT

A semiconductor device includes: a semiconductor element that has a first surface on which an electrode terminal is formed and a second surface opposite to the first surface; a resin mold portion in which the semiconductor element is embedded and that has a third surface exposing the first surface and a fourth surface opposite to the third surface; and a wiring layer formed on the third surface and the first surface, wherein a plurality of conducting portions are provided in the resin mold portion, which penetrate the resin mold portion along a thickness direction thereof to be electrically connected to the wiring layer.

### CROSS-REFERENCE TO RELATED APPLICATION

This application is based on and claims priority under 35 U.S.C. §119 from Japanese Patent Application. No. 2009-089223 filed on Apr. 1, 2009.

### BACKGROUND OF THE INVENTION

1. Field

The present invention is related to a semiconductor device and a method for manufacturing the semiconductor device.

2. Description of the Related Art

Among semiconductor devices, the below-mentioned semiconductor device product is present. That is, while the semiconductor device is equipped with resin mold portions molded by a resin in an integral manner with a semiconductor element, the surface direction of which is common to surfaces thereof where electrode terminals of the semiconductor element have been formed, a wiring layer which is electrically conducted to the semiconductor element is formed on the above-described surfaces of the resin mold portions, on which the electrodes terminals of the semiconductor element have been formed. In this semiconductor device, since an entire area of the semiconductor element and the resin mold portions (one-sided surfaces) constitute a wiring region, a wide wiring region can be secured, and a semiconductor element having multiple pins can be mounted thereon. Also, since the thicknesses of the resin mold portions become substantially equal to the thickness of the semiconductor element, the resulting semiconductor device may be provided as a slim type product.

### [Patent Publication 1] PCT Publication No. 02/15266

### [Patent Publication 2] PCT Publication No. 02/33751

Although the above-described semiconductor device may be provided as a slim type substrate board capable of mounting thereon the semiconductor element having the multiple pins, since the wiring layer is formed on one-sided surface of the substrate board, the below-mentioned problem occurs. That is, the above-described semiconductor device is not properly applied to such a utilization field that while plural sets of the above-explained semiconductor devices are electrically connected to each other, these semiconductor devices are stacked on each other in order to manufacture a composite substrate board.

### SUMMARY OF THE INVENTION

The present invention has an object to provide a semiconductor device and a manufacturing method thereof, which can be readily applied to such a utilization field that while a plurality of substrate boards can be electrically conducted to each other along a thickness direction of the substrate boards, the substrate boards are stacked on each other so as to form a composite substrate board.

According to a first aspect of the invention, there is provided a semiconductor device including:

a semiconductor element that has a first surface on which an electrode terminal is formed and a second surface opposite to the first surface;

a resin mold portion in which the semiconductor element is embedded and that has a third surface exposing the first surface and a fourth surface opposite to the third surface; and

a wiring layer formed on the third surface and the first surface, wherein

a plurality of conducting portions are provided in the resin mold portion, which penetrate the resin mold portion along a thickness direction thereof to be electrically connected to the wiring layer.

According to a second aspect of the invention, there is provided the semiconductor device including:

the semiconductor devices as in the first aspect stacked on each other in a plurality of stages along a thickness direction thereof, wherein

one semiconductor device and another semiconductor device provided along a stacking direction are electrically conducted and joined to each other via a joining member arranged between the conducting portion provided in the one semiconductor device and a land which is provided in the wiring layer of the another semiconductor device and is located opposite to the conducting portion.

According to a third aspect of the invention, there is provided the semiconductor device as in the second aspect, wherein

the conducting portions are provided in a surface array which is common to each of the semiconductor devices.

According to a fourth aspect of the invention, there is provided the semiconductor device as in the first aspect, wherein

the second surface of the semiconductor element is exposed to the fourth surface of the resin mold portion; and

the second surface of the semiconductor element and the fourth surface of the resin mold portion are formed on a common surface.

According to a fifth aspect of the invention, there is provided the semiconductor device as in the first aspect, wherein

the second surface of the semiconductor element is embedded in the resin mold portion.

According to a sixth aspect of the invention, there is provided the semiconductor device as in the first aspect, further including:

a heat radiating plate which is joined to the second surface of the semiconductor element.

According to a seventh aspect of the invention, there is provided the semiconductor device as in the first aspect, further including:

an electronic component which is electrically connected to the conducting portions and is mounted on the fourth surface of the resin mold portion.

According to an eighth aspect of the invention, there is provided the semiconductor device as in the seventh aspect, wherein

the electronic component mounted on the fourth surface of the resin mold portion is sealed by employing a resin.

According to a ninth aspect of the invention, there is provided a method for manufacturing a semiconductor device, including:

arranging a conducting portion made of an electric conducting material on a supporting plate;

arranging a semiconductor element on the supporting plate in such a manner that the semiconductor element has a first surface on which an electrode terminal is formed and a second surface opposite to the first surface and that the first surface faces to the supporting plate;

sealing a surface of the supporting plate, on which the semiconductor element and the conducting portion are arranged, by employing a sealing resin;

grinding an outer surface of the sealing resin so as to expose a summit portion of the conducting portion to the ground outer surface of the sealing resin;

removing the supporting plate; and

forming a wiring layer on both the sealing resin surface on the side from which the supporting plate has been removed, and the first surface of the semiconductor element.

According to a tenth aspect of the invention, there is provided the method for manufacturing a semiconductor device as in the ninth aspect, wherein

arranging the conducting portion on the supporting plate, includes:

half-cutting a metal plate along a thickness direction thereof so as to form a projected portion which constitutes the conducting portion; and

arranging the conducting portion on the supporting plate by supporting the half-cut metal plate on the supporting plate and tearing the metal plate off from the supporting plate, while the projected portion is left.

According to an eleventh aspect of the invention, there is provided the method for manufacturing a semiconductor device as in the ninth aspect, wherein

in grinding, the outer surface of the sealing resin is ground up to such a thickness that the second surface of the semiconductor element is exposed from the outer surface of the sealing resin.

According to a twelfth aspect of the invention, there is provided the semiconductor device as in the first aspect, wherein

the conducting portions are formed in columnar shapes, and

ends of the conducting portions are exposed from the third surface of the resin mold portion and the other ends thereof are exposed from the fourth surface of the resin mold portion.

According to a thirteenth aspect of the invention, there is provided the semiconductor device as in the first aspect, wherein

an insulating layer is formed on the third surface of the resin mold portion and on the first surface of the semiconductor element;

the wiring layer is provided in a patterning formed on the insulating layer, and includes a via directly connected to the conducting portion and the electrode terminal.

### BRIEF DESCRIPTION OF THE DRAWINGS

A general architecture that implements the various features of the invention will now be described with reference to the drawings. The drawings and the associated descriptions are provided to illustrate embodiments of the invention and not limited the scope of the invention.

FIG. 1 is an exemplary sectional view for showing a structure of a semiconductor device according to an embodiment of the present invention;

FIG. 2 is an exemplary plan view for indicating the semiconductor device;

FIG. 3 is an exemplary sectional view for representing a structure constructed by stacking the semiconductor devices of FIG. 1 on each other;

FIG. 4 is an exemplary sectional view for showing another structure of the semiconductor device;

FIGS. 5A to 5E are explanatory diagrams for indicating steps of manufacturing the semiconductor device, according to the embodiment of the present invention; and

FIGS. 6A to 6E are explanatory diagrams for representing steps of manufacturing the semiconductor device, according to the embodiment of the present invention.

FIG. 7 is an explanatory sectional view for showing a structure of a semiconductor device which is completely embedded in the resin mold portion.

### DETAILED DESCRIPTION OF THE PREFERRED EMBODIMENTS

### Semiconductor Device

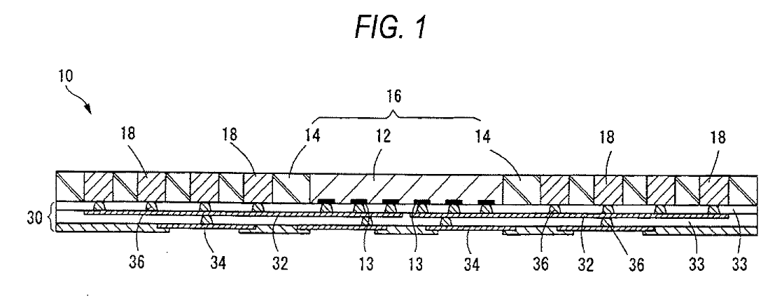

FIG. 1 is a sectional view for showing a structure of a semiconductor device 10 according to an embodiment mode of the present invention.

The semiconductor device 10 of the present embodiment mode is provided with a substrate board 16 and a wiring layer 30. The substrate board 16 is provided with a semiconductor element 12 and a resin mold portion 14 molded with the semiconductor element 12 in an integral manner in the form of a flat plate whose direction is common to a surface where electrode terminals 13 of the semiconductor element 12 have been formed. The wiring layer 30 is formed on one surface of the substrate board 16, on which the electrode terminals 13 of the semiconductor element 12 have been formed.

The wiring layer 30 is provided with wiring patterns 32 manufactured by being electrically connected to the electrode terminals 13. While lands 34 which join external connecting terminals (not shown) are provided on a surface of the wiring layer 30, both the wiring patterns 32 and the lands 34 are electrically connected through vias 36 to the electrode terminals 13. The wiring patterns 32 and the lands 34, which are formed in the wiring layer 30, are formed by defining an entire area of one surface of the substrate board 16 as a wiring region. Both the wiring patterns 32 and the lands 34, which are formed in the wiring layer 30, are manufactured in the form of proper patterns, and a total number of wiring layers may be properly set.

In the present embodiment mode, a thickness of the semiconductor element 12 is made equal to a thickness of the resin mold portion 14, and both surfaces (namely, front surface where electrode terminals 13 have been formed, and rear surface) of the semiconductor element 12, and both surfaces of the resin mold portion 14 are formed in such a manner that these both surfaces of the semiconductor elements 12 and the resin mold portion 14 become common surfaces (equal, or uniform surfaces) respectively. The rear surface of the semiconductor element 12 is exposed to the other surface of the substrate board 16.

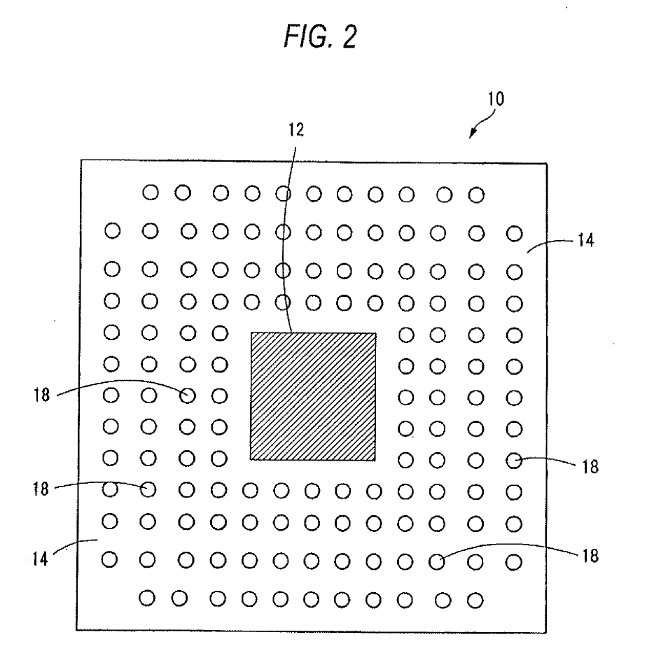

FIG. 2 indicates a situation under which the semiconductor device 10 is viewed from the surface direction thereof. While the semiconductor element 12 whose surface shape is a square is arranged at a center, the resin mold portion 14 whose outer shape is a square is formed in such a manner that the resin mold portion 14 surrounds the semiconductor element 12.

Conducting portions 18 are formed in the resin mold portion 14 at arranging positions where the conducting portions 18 penetrate the resin mold portion 14 along a thickness direction thereof. In the semiconductor device 10 shown in the drawings, the conducting portions 18 have been arranged in a lattice shape along longitudinal and lateral directions. Alternatively, the conducting portions 18 may be set in an arbitrary surface array such as a staggered arrangement.

As shown in FIG. 1, the conducting portions 18 are electrically connected to the wiring patterns 32 through the vias 36 formed in the wiring layer 30 on the surfaces (one-sided surfaces) of the conducting portions 18, which are located opposite to the wiring layer 30, and the other surfaces thereof are exposed to the outer surfaces of the resin mold portion 14.

The conducting portions 18 are employed in order to establish electric conduction of the semiconductor device 10 along a thickness direction thereof, and are manufactured by employing an electric conducting material such as copper. In FIG. 1, the conducting portions 18 are presently formed in cylindrical shapes and made of copper. The surface shapes of the conducting portions 18 may be alternatively made in a circular shape, or may be properly made in a polygonal shape. If materials have electric conducting characteristics, then the conducting portions 18 may properly utilize other metal materials and electric conducting materials than the above-described copper material. Since the copper material has a superior electric conducting characteristic and a better shape holding characteristic, the copper material may be effectively utilized.

A thickness of the semiconductor device 10 may be arbitrarily set. The thickness of the semiconductor device 10 which is normally used is of the order of 100 to 700 μm. While a thickness of the wiring layer 30 is of the order of 20 to 50 μm, this thickness is considerably thinner than a thickness of the substrate board 16 of the semiconductor device 10. For the sake of an easy explanation, FIG. 1 has illustrated that the thickness of the wiring layer 30 is made thicker than that of the substrate board 16. A thickness of the conducting portions 18 formed in the resin mold portion 14 is of the order of 100 μm to 700 μm.

### (Composite Semiconductor Device)

In the semiconductor device 10 of the present embodiment mode, the conducting portions 18 are provided in the resin mold portion 14, so that either a substrate board or an electronic product, which is arranged on the upper surface (namely, surface of semiconductor element 12 located opposite to surface where electrode terminals 13 have been formed) side of the semiconductor device 10, can be electrically connected to the wiring layer 30 via the conducting portions 18.

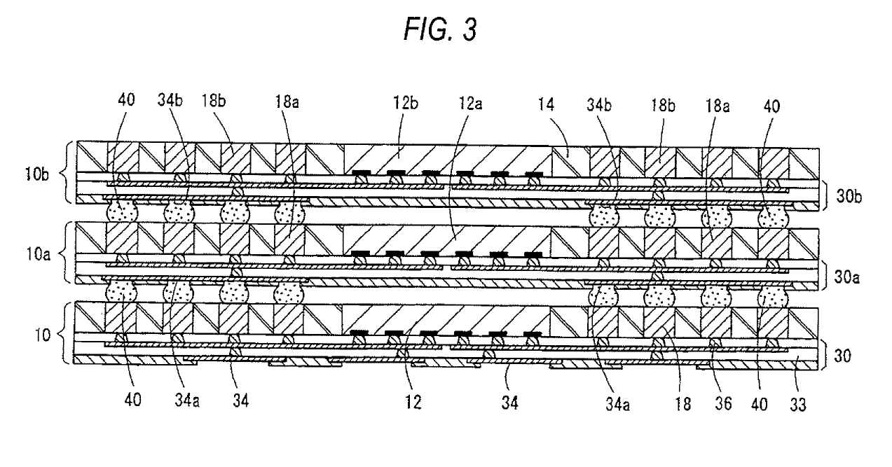

FIG. 3 shows an example of a semiconductor device (composite semiconductor device) manufactured by stacking a plurality of the above-described semiconductor devices 10 on each other. The above-described composite semiconductor device is an example of a semiconductor device assembled by stacking three sheets (3 pieces) of semiconductor devices 10, 10a, and 10b.

The semiconductor device 10 of a first stage is electrically connected to the semiconductor device 10a of a second stage by joining the conducting portions 18 of the semiconductor device 10 at the lower stage to lands 34a of a wiring layer 30a of the semiconductor device 10a at the upper stage via solder balls 40 functioning as a joining member. The semiconductor device 10a of the second stage is electrically connected to the semiconductor device 10b of the third stage by joining conducting portions 18a of the semiconductor device 10a at the second stage to lands 34b formed on a wiring layer 30b of the semiconductor device 10b at the third stage via solder balls 40.

Since the semiconductor device 10 of the first stage is joined via the solder balls 40 to the semiconductor device 10a of the second stage, the lands 34a to be formed on the semiconductor device 10a of the second stage are formed in such a manner that these lands 34a are arranged on the same surface as that of the conducting portions 18 (lands 34a and conducting portions 18 are arranged opposite to each other). It should be understood that the lands 34a need not be electrically connected to all the conducting portions 18, but may be alternatively set by that a certain number of the conducting portions 18 are selected, and only the selected conducting portions 18 are electrically connected to the lands 34a.

Also, as to the semiconductor devices 10a and 10b of the second stage and the third stage, arranging of the lands 34b to be provided in the wiring layer 30b of the semiconductor device 10b of the third stage is set on the same surface arrangement as that of the conducting portions 18a.

The surface arrays of the conducting portions 18, 18a, 18b, which are provided in the semiconductor devices 10, 10a, 10b, are common arrays; and if necessary, the surface arrays of the lands 34a and 34b, which are provided on the semiconductor devices 10a and 10b, are set to the same array as the surface arrays of the conducting portions 18, 18a, 18b, so that arbitrary stages (four, or more stages) of semiconductor devices can be stacked on each other in order that a composite semiconductor device can be easily manufactured. As a consequence, general-purpose characteristics of the semiconductor devices may be improved.

The composite semiconductor device of the present embodiment mode shown in FIG. 3 is an example that the solder balls 40 are used as the joining member. As methods capable of electrically connecting and joining the semiconductor devices 10, 10a, 10b with each other among the plural stages, the below-mentioned methods in addition to the method using the solder balls 40 may be utilized as follows, namely, a method for joining bumps such as gold bumps to the lands 34a and 34b and for soldering the conducting portions 18 and 18a to the bumps; another method for connecting the semiconductor devices 10, 10a, 10b to each other by utilizing an isotropic conducting film; a further method for connecting the semiconductor devices 10, 10a, 10b to each other by utilizing an electric conductive material such as solder paste and electric conducting paste; and other connecting methods.

While sorts of semiconductor elements 12, 12a, 12b, which are mounted on the semiconductor devices 10, 10a, 10b respectively, are properly selectable, since semiconductor elements to be mounted on the semiconductor devices 10, 10a, 10b are properly selected, composite semiconductor devices may be provided in correspondence with utilization fields.

For example, a CPU or a memory is employed as the semiconductor device.

It should also be noted that as semiconductor elements which are mounted on semiconductor devices, arbitrary sorts of semiconductor elements may be selected. Moreover, there is no limitation that semiconductor elements having same dimensions and same thicknesses must be necessarily mounted on the semiconductor devices. Further, although a single semiconductor element has been mounted within a single substrate board in the above-described example, a plurality of semiconductor elements may be alternatively mounted within a single substrate board. In the case that a plurality of semiconductor elements are mounted, these semiconductor elements may be collected at a center portion of the substrate board 16 so as to be positioned at this center portion, or may be alternatively arranged in such a manner that these semiconductor elements are distributed within the surface region of the substrate board 16.

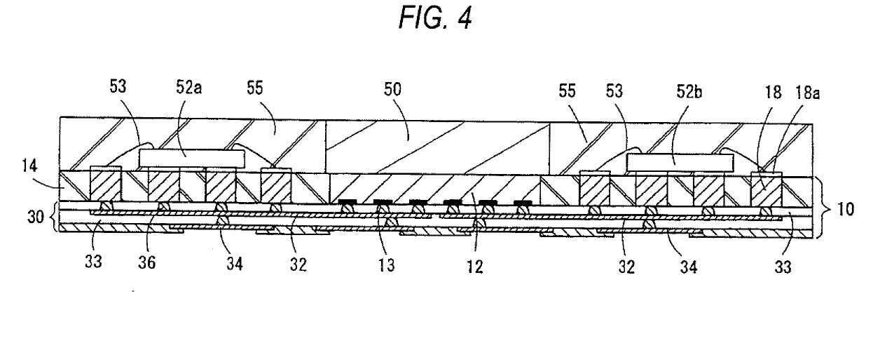

FIG. 4 indicates an example of a semiconductor device in which a heat radiation plate 50 of a semiconductor element 12, and electronic components 52a and 52b have been mounted on the other surface of a substrate board 16.

The heat radiating plate 50 has been mounted in such a manner that a lower surface thereof abuts against a rear surface of the semiconductor element 12. The electronic components 52a and 52b are semiconductor elements, and have been arranged in an area outside the area where the heat radiating plate 50 has been arranged, while the semiconductor elements 52a and 52b have been electrically connected to the conducting portions 18 by wire bonding.

The semiconductor elements 52a and 52b are electrically connected to the conducting portions 18 by bonding wires 53, the wiring layer 30 is electrically connected to the semiconductor elements 52a and 52b, and the semiconductor elements 52a and 52b are electrically connected to the semiconductor element 12.

As methods for electrically connecting the semiconductor element 52a and 52b to the conducting portions 18, not only the wire bonding method, but also another connecting method similar to a flip chip method may be employed. That is, in the flip chip method, while electrode terminal forming surfaces of the semiconductor elements 52a and 52b are located opposite to edge surfaces (upper surfaces) of the conducting portions 18, the electrode terminals are directly connected to the conducting portions 18.

The heat radiating plate 50 and the semiconductor elements 52a and 52b have been sealed on the other surface of the semiconductor device 10 by a sealing resin 55. The sealing resin 55 has sealed the heat radiating plate 50 and the semiconductor elements 52a and 52b in such a manner that an edge surface of the heat radiating surface 50 is exposed to the outer surface. The heat radiating plate 50 is mounted on the rear surface of the semiconductor element 12, and the edge surface (upper surface) of the heat radiating plate 50 is exposed from the sealing resin 55, so that heat can be radiated from the semiconductor element 12 in a higher efficiency. The structure of the above-described semiconductor device according to the present embodiment mode is an effective structure as such a semiconductor device which mounts thereon the semiconductor element 12 having a large heat generation amount.

Sealing of the heat radiating plate 50 and the semiconductor elements 52a and 52b by employing the sealing resin 55 can be carried out by employing a resin sealing apparatus. Since the semiconductor elements 52a and 52b including the bonding wires 53 are sealed by the sealing resin 55, reliability of the semiconductor device 10 can be improved.

It should also be understood that as the structure of the semiconductor device 10, another structure may be alternatively employed in which only the heat radiating plate 50 has been joined to the rear surface of the semiconductor element 12. In this alternative case, while the other surface of the substrate board 16 may not be sealed by employ a resin, the conducting portions 18 may be alternatively utilized as an electric connection for connecting the conducting portions 18 to the semiconductor device 10 stacked thereon. Otherwise, it is possible to employ another utilization method for using the semiconductor device 10 which has provided the heat radiating plate 50 at the uppermost stage.

It should also be noted that as structures in which electronic components such as the semiconductor elements 52a and 52b are mounted on the other surface of the substrate board 16, another structure capable of mounting thereon circuit components such as a chip capacitor and a chip resistor may be employed, and a further structure capable of mounting thereon these chip capacitor and chip resistor in a composite manner may be employed in addition to the above-described structure capable of mounting thereon the semiconductor elements 52a and 52b. Since semiconductor elements and arbitrarily selected circuit components are mounted on the other surface of the substrate board 16, semiconductor devices equipped with various sorts of utilization fields may be provided. It should also be understood that it is possible to provide a semiconductor device having such a structure that while the circuit elements 52a and 52b, and a circuit component are mounted on the other surface of the substrate board 16, the heat radiating plate 50 is not used. Also, there is no limitation that the semiconductor elements 52a and 52b and the circuit component must be always molded by a resin so as to be used.

### (Manufacturing Method of Semiconductor Device)

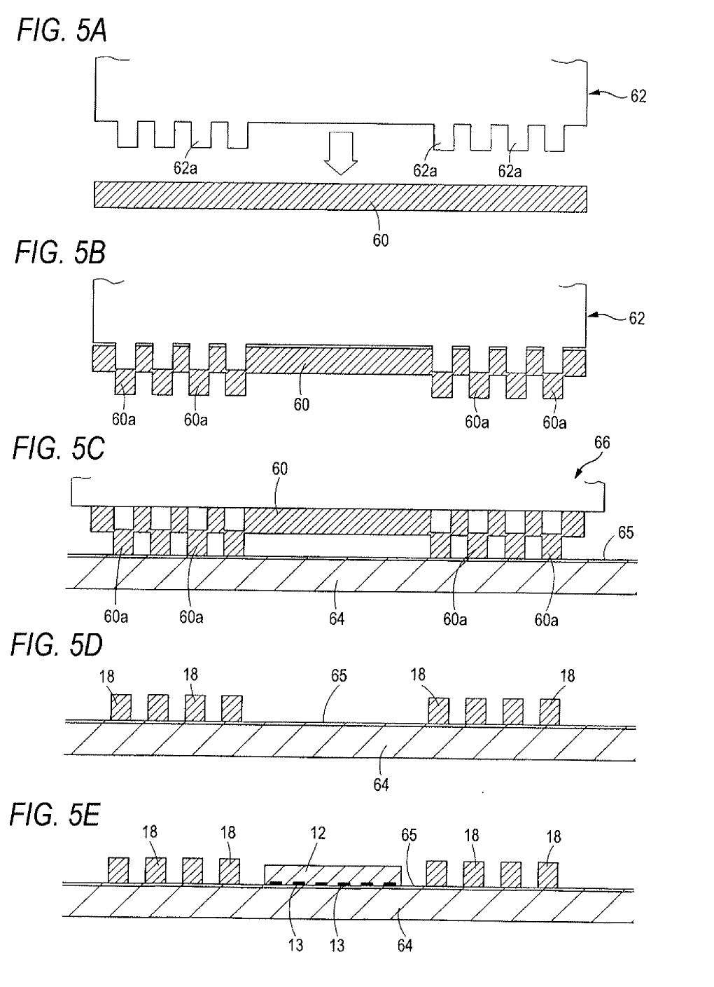

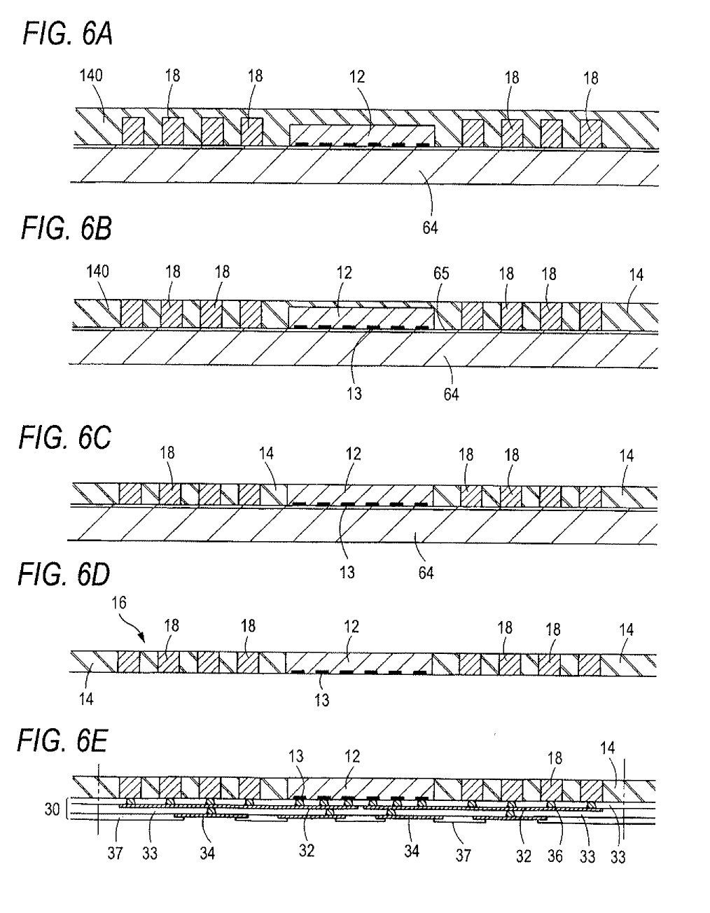

FIGS. 5A to 5E and FIGS. 6A to 6E indicate an example of manufacturing steps for a semiconductor device 10.

FIG. 5A shows a step (half cutting step) for half-cutting a copper plate 60 by employing a press die in order to form conducting portions 18. As a punch 62 of the press die, such a punch is employed which has projections 62a formed in an arrangement fitted to a surface arrangement of the conducting portions 18 to be formed in the semiconductor device 10. While shapes of edge surfaces of the projections 62a are made coincident with the shapes of the edge surfaces of the conducting portions 18 to be formed in the semiconductor device 10, these projections 62a are manufactured in such a manner that the projections 62a are elongated from an edge surface of the punch 62 which is slightly longer than a height (thickness) of the conducting portions 18.

It should be noted that in the manufacturing steps of the semiconductor device 10, a large number of the above-described semiconductor device 10 may be manufactured. As a consequence, a large-sized work by which large numbers of the semiconductor devices 10 may be manufactured is used as to the copper plate 60 for forming the conducting portions 18. For the sake of simple explanations, FIG. 5 and FIG. 6 show a portion of the work, which constitutes one of the plural semiconductor devices 10.

FIG. 5B represents a condition under which the copper plate 60 has been half-cut (half die cutting) by the punch 62. In FIG. 5B, the press die has been omitted. The punch 62 is pushed down toward the copper plate 60, so that the copper plate 60 is processed under such a mode that projected portions 60a are projected from the copper plate 60 (processing step of projected portions). The projected portions 60a are projected in cylindrical forms having the same edge surface shapes as the edge surface shapes of the projections 62a.

The process for half-cutting the copper plate 60 implies that when the copper plate 60 is die-cut along the thickness direction thereof, the copper plate 60 is processed under such a mode that base portions of the projected portions 60a are slightly being coupled to the copper plate 60. Since the copper plate 60 is processed in such a manner that a thickness of coupled portions between the projected portions 60a and the copper plate 60 is made thin, the projected portions 60a can be simply separated from the copper plate 60 in the succeeding step.

FIG. 5C shows a condition under which the copper plate 60 where the projected portions 60a have been formed are adhered to a supporting plate 64 so as to be supported (supporting step of processed metal plate). A use purpose of the supporting plate 64 is to support a semiconductor element 12 and the like when the semiconductor element 12 is mounted; when resin mold portion 14 are molded; and when other processing operations are carried out. As to the supporting plate 64, if materials having predetermined shape holding characters are available, then properly selected materials such as metal plates, resin plates and glass plates may be employed.

In the present embodiment mode, while a copper plate is used as the supporting plate 64, an adhesive film is laminated on a surface of the copperplate; an adhesive layer 65 is formed on the surface of the supporting plate 64; and then, the copper plate 60 is depressed against the supporting plate 64 by a depressing jig 66 so as to adhere the copper plate 60 to the supporting plate 64.

FIG. 5D shows a condition under which a base portion of the copper plate 60 is removed from the supporting plate 64 while the projected portions 60a are left on the supporting plate 64, and then, conducting portions 18 are formed on the supporting plate 64 (conducting portion forming step). When the base portion of the copper plate 60 is upwardly torn off under such a condition that the lower surfaces of the projected portions 60a are adhered onto the supporting plate 64, the projected portions 60a are separated from the base portion of the copper plate 60; and, as represented in FIG. 5D, the conducting portions 18 are left under such a supporting condition that the conducting portions 18 are raised on the supporting plate 64.

Further, it can be that the cooper plate 60 provided with the projected portions 60a is arranged above the supporting plate 64 with the interval between the projected portion 60a and the adhesive layer 65 of several hundreds μm, and the projected portions 60a are separated from the copperplate 60 by punching off by the NC punch to adhere the conducting portions 18 to the adhesive layer 65 of the supporting plate 64.

Next, as shown in FIG. 5E, the semiconductor element 12 is joined to a predetermined position on the supporting plate 64 so as to be fixed at this position. The semiconductor element 12 is adhered to and fixed on the supporting plate 64 by the adhesive layer 65, while the surface of the semiconductor element 12 where electrode terminals 13 have been formed is directed to the supporting plate 64. As represented in FIG. 5D, the conducting portions 18 are arranged around a region where the semiconductor element 12 is mounted, and the region where the semiconductor element 12 is mounted constitutes an empty region. The semiconductor element 12 is mounted on this semiconductor element mounting region, namely, the empty region.

Alternatively, the below-mentioned step may be realized. That is, under such a condition that the semiconductor element 12 has been previously joined onto the supporting plate 64, the projected portions 60a may be joined to the supporting plate 64, and the conducting portions 18 may be left on the supporting plate 64 in the alternative step.

FIG. 6A indicates a condition under which the surface (one-sided surface) of the supporting plate 64 which supports the semiconductor element 12 and the conducting portions 18 is molded by employing a resin, and both the semiconductor element 12 and the conducting portions 18 are sealed by employing a sealing resin 140 (resin sealing step).

In order to seal both the semiconductor element 12 and the conducting portions 18 by employing the resin, an outer circumference of the supporting plate 64 is clamped by a resin sealing die; a cavity is formed on the side of the supporting plate 64 on which the semiconductor element 12 has been mounted; a resin such as an epoxy resin is filled into the cavity; and the filled resin may be hardened.

When the side of the supporting plate 64 on which the semiconductor element 12 has been mounted is sealed by the resin, a depth of the cavity is set in such a manner that portions of the conducting portions 18 up to summit surfaces (upper surfaces) thereof are embedded into the sealing resin 140, and then, the supporting plate 64 is sealed by the resin. FIG. 6A indicates a condition under which entire portions of the semiconductor element 12 and the conducting portions 18 have been embedded into the sealing resin 140 so as to be sealed.

Further, in the process shown in FIG. 6A, the sealing resin 140 may be provided by potting a resin such as epoxy or polyimide. Alternatively, the sealing resin 140 may be provided by laminating a resin film such as epoxy or polyimide in vacuum with heating and pressurizing.

Next, an outer surface of the sealing resin 140 is grinding-processed so as to cause the summit surfaces (upper surfaces) of the conducting portions 18 to be exposed to the outer surface of the sealing resin 140 (grinding process step). FIG. 6B shows a condition under which the outer surface of the sealing resin 140 is ground so as to cause the summit surfaces of the conducting portions 18 to be exposed to the outer surface of the sealing resin 140. Since the resin is processed based upon the above-described grinding process step, the summit surfaces of the conducting portions 18 are exposed in such a manner that the exposed summit surfaces constitute equal surfaces with respect to the outer surface of the sealing resin 140.

In FIG. 6B, under such a grinding condition that the outer surfaces of the resin mold portion 14 and the outer surfaces of the conducting portions 18 may become an equal flat surface, the rear surface of the semiconductor element 12 has been embedded in the resin mold portion 14.

FIG. 6C indicates a condition under which the grinding process of both the resin mold portion 14 and the conducting portions 18 is furthermore carried out in order that the rear surface of the semiconductor element 12 (namely, surface thereof located opposite to surface where electrode terminals 13 have been formed) is exposed to the outer surface of the resin mold portion 14.

It should also be understood that when the semiconductor device 10, 10a, or 10b is made thinner, the rear surface of the semiconductor element 12 may be ground in combination with the resin mold portion 14 and the conducting portions 18.

As shown in FIG. 6B, the semiconductor element 12 may be brought into such a condition that the semiconductor element 12 has been embedded into the resin mold portion 14, and also, an represented in FIG. 6C, the rear surface of the semiconductor element 12 may be exposed to the outer surfaces of the resin mold portion 14. The outer surface of the sealing resin 140 is grinding-processed, so that the outer surface (rear surface) of the semiconductor element 12, the outer surface of the sealing resin 140, and the outer surfaces of the conducting portions 18 may constitute surfaces having substantially equal heights.

If the semiconductor element 12 is brought into such a condition that the semiconductor element 12 has been embedded into the resin mold portion 14, then the semiconductor element is sealed by the resin, so that reliability of a semiconductor device may be improved. Also, since the thicknesses of the resin mold portion 14 is increased, a shape holding characteristic and a strength of the semiconductor device may be improved.

If the rear surface of the semiconductor element 12 is exposed from the resin mold portion 14, then a heat dissipating characteristic from the semiconductor element 12 becomes better, and since a heat radiating plate is mounted on the rear surface of the semiconductor element 12, a heat radiating characteristic becomes better. Also, since the portion of the semiconductor element 12 up to the rear surface side thereof is ground, a thickness of a semiconductor device may be reduced, so that the semiconductor device may be made slim under such a condition that the semiconductor element 12 has been mounted.

It should be noted that in the present embodiment mode, as shown in FIG. 6B, in the step for half-cutting the copper plate 60 in such a manner that the semiconductor element 12 is embedded into the resin mold portion 14 so as to be sealed by the resin, the heights of the projected portions 60a have been set to become higher than the thickness of the semiconductor element 12. In such a structural case that the rear surface of the semiconductor element 12 is exposed to the outer surfaces of the resin forming portions 14, it is preferable that the heights of the projected portions 60a may be processed so as to become substantially equal to the thickness of the semiconductor element 12. This reason is given as follows: That is, a grinding work of the resin mold portion 14 in a succeeding step may be omitted, or may be easily carried out.

As shown in FIG. 4, in the case that the heat radiating plate 50 is arranged on the rear surface of the semiconductor element 12 and an electronic component such as a semiconductor element is mounted on the side of a rear surface of a substrate board, under the condition of FIG. 6C, the heat radiating plate 50 is joined to the rear surface of the semiconductor element 12, and the semiconductor elements 52a and 52b are mounted, and thereafter, the supporting plate 64 is clamped by a resin mold die, and one-sided surface of the supporting plate 64 on which the semiconductor element 12 has been mounted may be sealed by employing a resin. The surface of the sealing resin 55 may be grinding-processed in such a mariner that the edge surface of the heat radiating plate 50 is exposed, if necessary.

The supporting plate 64 is removed from the conditions represented in FIGS. 6B and 6C, and a substrate board 16 constructed of the semiconductor element 12 and the resin mold portion 14 is formed (supporting plate removing step)

FIG. 6D indicates a condition under which the supporting plate 64 is removed from the condition shown in FIG. 6C, and the substrate board 16 is obtained in which the resin mold portion 14 have been formed in the integral manner with the semiconductor element 12 at an arrangement for surrounding the side surface of the semiconductor element 12. The conducting portions 18 which penetrate the resin mold portion 14 along the thickness direction thereof are provided in the resin mold portion 14.

The lower surfaces of the resin mold portion 14, which were contacted to the supporting plate 64, the lower surfaces of the conducting portions 18, and the electrode terminal forming surface of the semiconductor element 12 are formed in a substantially equal flat surface.

As methods for removing the supporting plate 64, a method for chemically etching the supporting plate 64 so as to remove the etched supporting plate 64 based upon a material of the supporting plate 64, another method for lowering the adhesive characteristic of the adhesive layer 65 and mechanically tearing off the supporting plate 64 so as to remove the supporting plate 64, and other methods may be selectively carried out. In the case that the adhesive layer 65 is still left on the substrate board 16, only the adhesive layer 65 may be etched in either a chemical manner or a physical manner so as to remove the supporting plate 64.

After the supporting plate 64 is removed, a wiring layer 30 is formed on one surface of the substrate board 16 (namely, surface of substrate board 16, on which electrode terminals 13 of semiconductor element 12 have been formed). The wiring layer 30 is formed by applying a general-purpose method for manufacturing a wiring substrate such as a build-up method. For instance, films made of an epoxy resin are stacked on each other so as to form insulating layers 33; via holes are formed in the insulating layers 33 by a laser process; and then, vias and wiring patterns 32 are formed by utilizing a semi-additive method. In the insulating layers 33 which are contacted to the electrode terminal forming surface of the semiconductor element 12 and the conducting portions 18, both vias 36 are formed which are connected to the electrode terminals 13 of the semiconductor element 12, and vias 36 are formed which are connected to the lower surfaces of the conducting portion 18, so that the semiconductor element 12 is electrically connected to the conducting portions 18 through the wiring patterns 32 provided within the surfaces of the insulating layers 33.

The wiring patterns 32 between the layers are electrically connected to each other through the vias 36. It should also be noted that a total number of stacked layers of the wiring patterns, and arrangements of the wiring patterns within the wiring layer 30 may be properly set.

While lands 34 to which external connecting terminals (not shown) are joined are formed on the lowermost surface of the wiring layer 30, the surface of the wiring layer 30 is covered by a protection film 37 such as a solder resist except for the surface portion where the lands 34 have been formed. Protection plating such as gold plating is performed on the lands 34. It is preferable to construct that protection plating (anti-corrosion plating) such as gold plating may also be performed with respect to the edge surfaces of the conducting portions 18, which are exposed from the resin mold portion 14, so that when solder balls are joined to the conducting portions 18 and the conducting portions 18 are connected by wiring bonding, the conducting portions 18 may be firmly joined to these members.

After the wiring layer 30 has been formed on a large-sized work (not shown), this work is cut along a two-dot chain line shown in FIG. 6E so as to obtain an individual semiconductor device, so that the semiconductor device 10 shown in FIG. 1 may be obtained.

In the manufacturing method of the semiconductor device according to the present embodiment mode, the copper plate 60 is pressed so as to form the projected portions 60a which constitute the conducting portions 18. Since the projected portions 60a are formed by the press working, even in such a case that heights of the projected portions 60a are several hundreds μm, the projected portions 60a can be simply formed. Furthermore, since the projected portions 60a are formed by the press working, surface arranging positions and surface shapes of the projected portions 60a can be arbitrarily set and can be manufactured by mass production.

In the present embodiment mode, both the conducting portions 18 and the semiconductor element 12 are arranged on the supporting plate 64, and then, the substrate board 16 is formed by utilizing the resin forming method. As a consequence, since the arrangements as to the conducting portions 18 and the semiconductor element 12 on the supporting plate 64 are properly selected, various sorts of semiconductor devices can be manufactured, and such a semiconductor device that the plurality of semiconductor elements are mounted within a single semiconductor device can be easily manufactured.

The conducting portions 18 are provided on the supporting plate 64 based upon a predetermined array. The method for forming the conducting portions 18 is not limited only to the above-described method for pressing the metal plate such as the copper plate 60 so as to form the conducting portions 18. Alternatively, for instance, the conducting portions 18 may be formed on the supporting plate 64 by performing a plating method. In other words, while a resist film having a height more than that of the conducting portions 18 is laminated on the supporting plate 64, a resist pattern is formed on the laminated resist film, by which portions used to form the conducting portions 18 become concave portions by exposing and developing operations, and then, copper plating is raised within the concave portions by electrolytic copper plating, so that the conducting portions 18 may be formed.

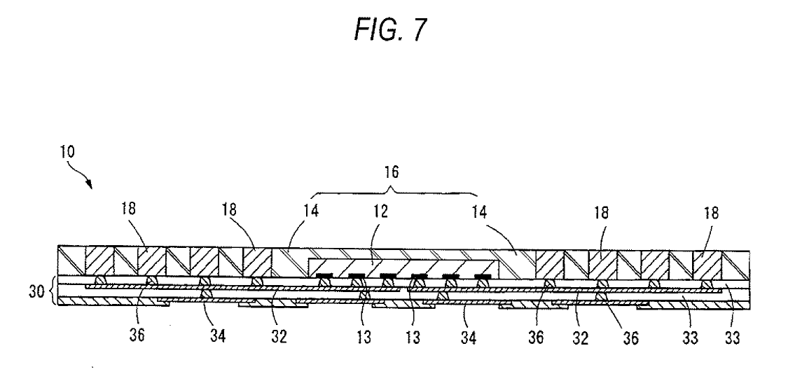

Besides, if the semiconductor 12 is processed by the manufacturing steps shown in FIGS. 6D and 6E with being embedded in the sealing resin 140 (resin mold portion 14) as shown in FIG. 6B, the semiconductor device as shown in FIG. 7 is provided.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

What is claimed is:

1. A semiconductor device comprising:
a semiconductor element that has a first surface on which an electrode terminal is formed and a second surface opposite to the first surface;
a resin mold portion in which the semiconductor element is embedded and that has a third surface exposing the first surface and a fourth surface opposite to the third surface; and
a wiring layer formed on the third surface and the first surface, wherein
a plurality of conducting portions are provided in the resin mold portion, which penetrate the resin mold portion along a thickness direction thereof to be electrically connected to the wiring layer.

2. The semiconductor device comprising:
the semiconductor devices as in claim 1 stacked on each other in a plurality of stages along a thickness direction thereof, wherein
one semiconductor device and another semiconductor device provided along a stacking direction are electrically conducted and joined to each other via a joining member arranged between the conducting portion provided in the one semiconductor device and a land which is provided in the wiring layer of the another semiconductor device and is located opposite to the conducting portion.

3. The semiconductor device as in claim 2, wherein
the conducting portions are provided in a surface array which is common to each of the semiconductor devices.

4. The semiconductor device as in claim 1, wherein
the second surface of the semiconductor element is exposed to the fourth surface of the resin mold portion; and
the second surface of the semiconductor element and the fourth surface of the resin mold portion are formed on a common surface.

5. The semiconductor device as in claim 1, wherein
the second surface of the semiconductor element is embedded in the resin mold portion.

6. The semiconductor device as in claim 1, further comprising:
a heat radiating plate which is joined to the second surface of the semiconductor element.

7. The semiconductor device as in claim 1, further comprising:
an electronic component which is electrically connected to the conducting portions and is mounted on the fourth surface of the resin mold portion.

8. The semiconductor device as in claim 7, wherein
the electronic component mounted on the fourth surface of the resin mold portion is sealed by employing a resin.

9. A method for manufacturing a semiconductor device, comprising:
arranging a conducting portion made of an electric conducting material on a supporting plate;
arranging a semiconductor element on the supporting plate in such a manner that the semiconductor element has a first surface on which an electrode terminal is formed and a second surface opposite to the first surface and that the first surface faces to the supporting plate;
sealing a surface of the supporting plate, on which the semiconductor element and the conducting portion are arranged, by employing a sealing resin;
grinding an outer surface of the sealing resin so as to expose a summit portion of the conducting portion to the ground outer surface of the sealing resin;
removing the supporting plate; and
forming a wiring layer on both the sealing resin surface on the side from which the supporting plate has been removed, and the first surface of the semiconductor element.

10. The method for manufacturing a semiconductor device as in claim 9, wherein
arranging the conducting portion on the supporting plate, comprises:
half-cutting a metal plate along a thickness direction thereof so as to form a projected portion which constitutes the conducting portion; and
arranging the conducting portion on the supporting plate by supporting the half-cut metal plate on the supporting plate and tearing the metal plate off from the supporting plate, while the projected portion is left.

11. The method for manufacturing a semiconductor device as in claim 9, wherein
in grinding, the outer surface of the sealing resin is ground up to such a thickness that the second surface of the semiconductor element is exposed from the outer surface of the sealing resin.

12. The semiconductor device as in claim 1, wherein
the conducting portions are formed in columnar shapes, and
ends of the conducting portions are exposed from the third surface of the resin mold portion and the other ends thereof are exposed from the fourth surface of the resin mold portion.

13. The semiconductor device as in claim 1, wherein
an insulating layer is formed on the third surface of the resin mold portion and on the first surface of the semiconductor element;
the wiring layer is provided in a patterning formed on the insulating layer, and comprises a via directly connected to the conducting portion and the electrode terminal.
